(19) United States
(12) Patent Application Publication
(10) Pub. No.: US 2012/0193118 A1
(43) Pub. Date: Aug. 2, 2012

(54) DIRECTLY APPLICABLE ELECTRICAL BUSHING

(75) Inventors: Mark Kempf, Inver Grove Heights, MN (US); Jens Troetzschel, Neuwiedermus (DE)

(73) Assignee: HERAEUS PRECIOUS MATERIALS GMBH & CO. KG, Hanau (DE)

(21) Appl. No.: 13/361,340

(22) Filed: Jan. 30, 2012

Related U.S. Application Data
(60) Provisional application No. 61/438,008, filed on Jan. 31, 2011.

(30) Foreign Application Priority Data
Jan. 31, 2011 (DE) 10 2011 009 866.6

(51) Int. Cl. H05K 5/06

(52) U.S. Cl. 174/50.53

(57) ABSTRACT

One aspect relates to an electrical bushing for use in a housing of an active implantable medical device, whereby the electrical bushing includes at least one electrically insulating base body and at least one electrical conducting element, whereby the conducting element establishes, through the base body, at least one electrically conductive connection between an internal space of the housing and an external space, whereby the conducting element is hermetically sealed with respect to the base body, and whereby the at least one conducting element includes at least one cermet.

One aspect provides the base body to include a contact region, whereby the base body can be connected to the housing in a firmly bonded manner by means of the contact region.

### CROSS-REFERENCE TO RELATED APPLICATIONS

This Non-Provisional Patent Application claims the benefit of the filing date of U.S. Provisional Patent Application Ser. No. 61/438,008, filed Jan. 31, 2011, entitled “DIRECTLY APPLICABLE ELECTRICAL BUSHING,” and this Patent Application also claims priority to German Patent Application No. DE 10 2011 009 866.6, filed on Jan. 31, 2011, and both of which are incorporated herein by reference.

### BACKGROUND

One aspect relates to an electrical bushing for use in a housing of an active implantable medical device.

The post-published document, DE 10 2009 035 972, discloses an electrical bushing for an implantable medical device having the features of the preamble of claim 1. Moreover, a use of at least one cermet-comprising conducting element in an electrical bushing for an implantable medical device and a method for the manufacture of an electrical bushing for an implantable medical device are disclosed.

A multitude of electrical bushings for various applications are known, examples including: U.S. Pat. No. 4,678,868, U.S. Pat. No. 7,564,674 B2, US 2008/0119906 A1, U.S. Pat. No. 7,145,076 B2, U.S. Pat. No. 7,561,917, US 2007/0183118 A1, U.S. Pat. No. 7,260,434B1, U.S. Pat. No. 7,761,165, U.S. Pat. No. 7,742,817 B2, U.S. Pat. No. 7,736,191 B1, US 2006/0259093 A1, U.S. Pat. No. 7,274,963 B2, US 2004116976 A1, U.S. Pat. No. 7,794,256, US 2010/0023086 A1, U.S. Pat. No. 7,502,217 B2, U.S. Pat. No. 7,706,124 B2, U.S. Pat. No. 6,999,818 B2, EP 1754511 A2, U.S. Pat. No. 7,035,076, EP 1685874 A1, WO 03/073450 A1, U.S. Pat. No. 7,136,273, U.S. Pat. No. 7,765,005, WO 2008/103166 A1, US 2008/0269831, U.S. Pat. No. 7,174,219 B2, WO 2004/110555 A1, U.S. Pat. No. 7,720,538 B2, WO 2010/091435, US 2010/0258342 A1, US 2001/0013756 A1, U.S. Pat. No. 4,315,054, and EP 0877400.

From DE 10 2008 021 064 A1 is known a connection housing for an electrical medical implant having contact sockets for accommoding and contacting electrode lead plugs. The connection housing includes a base module and a separately fabricated lid module, which is inserted into the base module and connected to it and has a contact socket that complies with the IS-4 standard.

From US 2008/0119906 A1 is known a hermetically sealed electrical bushing for cardiac pacemakers and defibrillators. Said bushing includes a flat ceramic disc that is used as an insulating support. The insulating disc includes openings, into which various electrodes are inserted as through-going contacts. Moreover, a metal flange is disclosed through which the ceramic disc can be connected to a housing.

From U.S. Pat. No. 7,260,434 is known a bushing device for an implantable medical device. It includes a plurality of filtered feedthrough arrangements each of which extends through an insulating base.

DE 697 297 19 T2 describes an electrical bushing for an active implantable medical device—also called implantable device or therapeutic device. Electrical bushings of this type serve to establish an electrical connection between a hermetically sealed interior and an exterior of the therapeutic device. Known implantable therapeutic devices are cardiac pacemakers or defibrillators, which usually include a hermetically sealed metal housing which is provided with a connection body, also called header, on one of its sides. Said connection body includes a hollow space having at least one connection socket for connecting electrode leads. In this context, the connection socket includes electrical contacts in order to electrically connect the electrode leads to the control electronics on the interior of the housing of the implantable therapeutic device. Hermetic sealing with respect to a surrounding is an essential prerequisite of an electrical bushing of this type. Therefore, lead wires that are introduced into an electrically insulating base body, also called signal-transmission elements, through which the electrical signals are propagated, must be introduced into the base body such as to be free of gaps.

In this context, it has proven to be challenging that the lead wires generally are made of a metal and are introduced into a ceramic base body. In order to ensure durable connection between the two elements, the internal surface of a through-opening—also called openings—in the base body is metallized for attachment of the lead wires by soldering. However, the metallization in the through-opening has proven to be difficult to apply. Only expensive procedures ensure homogeneous metallization of the internal surface of the bore hole—and thus a hermetically sealed connection of the lead wires to the base body by soldering. The soldering process itself requires additional components, such as solder rings. Moreover, the process of connecting the lead wires to the previously metallized insulators utilizing the solder rings is a process that is laborious and difficult to automate. For these and other reasons there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Further measures and advantages of the invention are evident from the claims, the description provided hereinafter, and the drawings. The invention is illustrated through several exemplary embodiments in the drawings. In this context, equal or functionally equal or functionally corresponding elements are identified through the same reference numbers. The invention shall not be limited to the exemplary embodiments.

FIG. 1 illustrates an active implantable medical device.

FIG. 2 illustrates an electrical bushing according to one embodiment that is connected to a housing in a firmly bonded manner.

FIG. 3 illustrates a magnified detail of region I from FIG. 2.

FIG. 4 illustrates another variant of an embodiment of the electrical bushing according to one embodiment.

FIG. 5 illustrates yet another variant of an embodiment of the electrical bushing according to one embodiment having a centering element.

FIG. 6 illustrates another variant of an embodiment of the electrical bushing according to one embodiment having another variant of an embodiment of the centering element.

FIG. 7 illustrates a bushing support having two electrical bushings according to one embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

One aspect specifies an electrical bushing for use in a housing of an active implantable medical device that is, for example, inexpensive to manufacture and enables a hermetically sealed connection to the housing of an active implantable medical device to be attained, and which in general overcomes, at least in part, the resulting disadvantages according to the prior art.

The subject matter of the category-forming claim contributes to the resolution of at least one of the objects. The sub-claims that depend on said claim are refinements of said subject matter.

One aspect relates to an electrical bushing for use in a housing of an active implantable medical device, whereby the electrical bushing includes at least one electrically insulating base body and at least one electrical conducting element, whereby the conducting element is set up to establish, through the base body, at least one electrically conductive connection between an internal space of the housing and an external space, whereby the conducting element is hermetically sealed with respect to the base body, whereby the at least one conducting element includes at least one cermet. One embodiment provides the base body to include a contact region, whereby the base body can be contacted to the housing in a firmly bonded manner by means of the contact region.

The electrical bushing according to one embodiment is characterized in that it can be connected directly to the housing. Known electrical bushings include a frame-like element that surrounds the base body and is made from a metal. Said frame-like element is utilized to insert the electrical bushing into an opening of the housing. In contrast, the electrical bushing disclosed herein is designed such that it bridges an opening in a housing of an active implantable medical device—which shall be called medical device hereinafter. Accordingly, the electrical bushing is connected directly to the housing and designed without a frame. Dispensing with a frame not only reduces the costs of the manufacture of an electrical bushing, but also reduces the number of firmly bonded connections in a medical device.

This is advantageous in one embodiment in that each firmly bonded connection is a potential weak spot through which ambient influences, such as body fluids, may penetrate into the medical device. The electrical bushing according to one embodiment includes a contact region that enables said direct firmly bonded connection between housing and electrical bushing. Various options of designing the contact region and the electrical bushing according to embodiments shall be disclosed in the following.

The proposed electrical bushing is set up for use in an implantable medical device, that is, for application in an implantable medical device, whereby the implantable medical device can be provided, for example, as an active implantable medical device (AIMD) and, for example, as a therapeutic device.

As a general rule, the term, implantable medical device, shall include any device which is set up to perform at least one medical function and which can be introduced into a body tissue of a human or animal user. As a general rule, the medical function can include any function selected from the group consisting of a therapeutic function, a diagnostic function, and a surgical function. The medical function can, for example, include a function, in which at least one stimulus is exerted on the body tissue, for example, an electrical stimulus. Said stimulating function can be exerted, for example, by means of at least one stimulus generator and/or by means of at least one stimulus transmitter, for example by means of an actuator. However, other types of exerting a stimulus are also feasible as a matter of principle.

As a matter of principle, the term, active implantable medical device—also called AIMD—shall include all implantable medical devices that can conduct electrical signals from a hermetically sealed housing to a part of the body tissue of the user and/or receive electrical signals from the part of the body tissue of the user. Accordingly, the term, active implantable medical device, includes, for example, cardiac pacemakers, cochlea implants, implantable cardioverters/defibrillators, nerve, brain, organ or muscle stimulators as well as implantable monitoring devices, hearing aids, retinal implants, muscle stimulators, implantable drug pumps, artificial hearts, bone growth stimulators, prostate implants, stomach implants or the like.

The implantable medical device, for example, the active implantable medical device, includes at least one housing, for example, at least one hermetically sealed housing. The housing can enclose at least one electronics unit, for example a triggering and/or analytical electronics unit of the implantable medical device.

According to the scope of an embodiment, a housing of an implantable medical device shall be understood to be an element that encloses, at least in part, at least one functional element of the implantable medical device that is set up to perform the at least one medical function or promotes the medical function. For example, the housing includes at least one internal space that takes up the functional element fully or in part. For example, the housing can be set up to provide mechanical protection to the functional element with respect to strains occurring during operation and/or upon handling, and/or provide protection to the functional element with respect to ambient influences such as, for example, influences of a body fluid. The housing can, for example, border and/or close the implantable medical device with respect to the outside.

In this context, an internal space shall be understood herein to mean a region of the implantable medical device, for example, within the housing, which can take up the functional element fully or in part and which, in an implanted state, does not contact the body tissue and/or a body fluid. The internal space can include at least one hollow space which can be closed fully or in part. However, alternatively, the internal space can be filled up fully or in part, for example by the at least one functional element and/or by at least one filling material, for example at least one casting, for example at least one casting material in the form of an epoxy resin or a similar material.

An external space, in contrast, shall be understood to be a region outside of the housing. This can, for example, be a region which, in the implanted state, can contact the body tissue and/or a body fluid. Alternatively or in addition, the external space can just as well be or include a region that is only accessible from outside the housing without necessarily contacting the body tissue and/or the body fluid, for example a region of a connecting element of the implantable medical device that is accessible from outside to an electrical connecting element, for example an electrical plug connector.

The housing and/or, for example, the electrical bushing can, for example, be provided to be hermetically sealed such that, for example, the internal space, is hermetically sealed with respect to the external space. In the scope of one embodiment, the term, “hermetically sealed”, can illustrate that moisture and/or gases cannot permeate through the hermetically sealed element at all or only to a minimal extent upon intended use for the common periods of time (for example 5-10 years). The so-called leak rate, which can be determined, for example, by leak tests, is a physical parameter that can describe, for example, a permeation of gases and/or moisture through a device, for example, through the electrical bushing and/or the housing. Pertinent leak tests can be carried out with helium leak testers and/or mass spectrometers and are specified in the Mil-STD-883G Method 1014 standard. In this context, the maximal permissible helium leak rate is determined as a function of the internal volume of the device to be tested. According to the methods specified in MIL-STD-883G, method 1014, section 3.1 and taking into consideration the volumes and cavities of the devices to be tested that are used in the application of one embodiment, said maximal permissible helium leak rates can, for example, be from 1×10⁻⁸ atm*cm³/sec to 1×10⁻⁷ atm*cm³/sec. In the scope of one embodiment, the term, “hermetically sealed”, shall be understood, for example, to mean that the device to be tested (for example the housing and/or the electrical bushing and/or the housing with the electrical bushing) has a helium leak rate of less than 1×10⁻⁷ atm*cm³/sec. In one embodiment, the helium leak rate can be less than 1×10⁻⁸ atm*cm³/sec, for example, less than 1×10⁻⁹ atm*cm³/sec. For the purpose of standardization, the above-mentioned helium leak rates can also be converted into the equivalent standard air leak rate. The definition of the equivalent standard air leak rate and the conversion are specified in the ISO 3530 standard.

Moreover, the housing can include a housing opening. The electrical bushing is arranged in and/or on and/or at the housing opening, in such a manner that the housing opening is closed in a hermetically sealed manner through the base body and/or the electrical bushing. The housing opening can basically have any cross-section, for example of a round, oval or polygonal shape, for example, a rectangular or square shape.

Electrical bushings are elements set up to create at least one electrically conductive path that extends between the internal space of the housing to at least one external point or region outside the housing, for example, situated in the external space. Accordingly, this establishes, for example, an electrical connection to leads, electrodes, and sensors that are arranged outside the housing.

Common implantable medical devices are commonly provided with a housing, which can include, on one side, a head part, also called header or connecting body, that carries connection sockets for connection of leads, also called electrode leads. The connection sockets include, for example, electrical contacts that serve to electrically connect the leads to a control electronics unit on the interior of the housing of the medical device. Usually, an electrical bushing is provided in the location, at which the electrical connection enters into the housing of the medical device, and the electrical bushing is inserted into a corresponding opening of the housing in a hermetically sealing manner.

Due to the type of use of implantable medical devices, their hermetic sealing and biocompatibility are usually amongst the foremost requirements. The implantable medical device proposed herein according to one embodiment, can be inserted, for example, into a body of a human or animal user, for example, of a patient. As a result, the implantable medical device is usually exposed to a fluid of a body tissue of the body. Accordingly, it is usually important that no body fluid penetrates into the implantable medical device and that no liquids leak from the implantable medical device. In order to ensure this, the housing of the implantable medical device, and thus the electrical bushing as well, should be as impermeable as possible, for example, with respect to body fluids.

Moreover, the electrical bushing should ensure high electrical insulation between the at least one conducting element and the housing and/or the multiple conducting elements provided that more than one conducting element are present. In this context, the insulation resistance reached is at least several MOhm, for example, more than 20 MOhm, and the leakage currents reached can be small, for example, less than 10 pA. Moreover, in case multiple conducting elements are present, the crosstalk and electromagnetic coupling between the individual conducting elements are below the specified thresholds for medical applications.

The electrical bushing disclosed according to one embodiment is well-suited for the above-mentioned applications. Moreover, the electrical bushing can also be used in other applications that are associated with special requirements with regard to biocompatibility, tight sealing, and stability.

The electrical bushing according to one embodiment can meet, for example, the above-mentioned tight sealing requirements and/or the above-mentioned insulation requirements.

The electrical bushing can basically take any shape, for example a round shape, an oval shape or a polygonal shape, for example, a rectangular or square shape, for example in a viewing direction towards a housing opening of the housing.

As mentioned above, the electrical bushing includes at least one electrically insulating base body. In the scope of one embodiment, a base body shall be understood to mean an element that serves a mechanical holding function in the electrical bushing, for example in that the base body holds or carries the at least one conducting element either directly or indirectly. For example, the at least one conducting element can be embedded in the base body directly or indirectly, fully or partly, for example, through a firmly bonded connection between the base body and the conducting element and, for example, through co-sintering of the base body and the conducting element. For example, the base body can have at least one side facing the internal space and at least one side facing the external space and/or accessible from the external space.

The base body and/or the centering element to be described in more detail below can, for example, be designed to be rotationally symmetrical about an axis, for example about an axis that is arranged to be essentially perpendicular to the housing opening. Accordingly, the base body and/or the centering element can take the shape of a disc, for example a disc with a round, oval or polygonal base surface. Alternatively, the base body and/or the centering element may just as well have a graduated shape, for example a shape of at least two discs of different diameters or equivalent diameters that are placed one on the other, which are, for example, in a concentric arrangement with respect to each other and which, for example, can have a round, an oval or a polygonal, for example, rectangular or square, cross-section. However, other designs are also feasible as a matter of principle.

As mentioned above, the base body is provided to be electrically insulating. This means that the base body, fully or at least regions thereof, is made from at least one electrically insulating material. For example, the at least one electrically insulating material can be arranged such that the at least one conducting element is electrically insulated with respect to the housing and/or, if multiple conducting elements are provided, that these are electrically insulated with respect to each other. In this context, an electrically insulating material shall be understood to mean a material with a resistivity of at least 10² Ohm*m, for example, of at least 10⁶ Ohm*m, for example, of at least 10¹⁰ Ohm*m, and for example, of at least 10¹² Ohm*m. For example, the base body can be provided such that, as mentioned above, a flow of current between the conducting element and the housing and/or between multiple conducting elements is prevented, at least largely, for example through the resistivity values between the conducting element and the housing as specified above being implemented. For example, the base body can include at least one ceramic material.

In this context, a conducting element or electrical conducting element shall generally be understood to mean an element set up to establish an electrical connection between at least two sites and/or at least two elements. For example, the conducting element can include one or more electrical conductors, for example metallic conductors. In the scope of one embodiment, the conducting element is made fully or partly of at least one cermet, as mentioned above. In addition, one or more other electrical conductors, for example metallic conductors, can be provided. The conducting element can, for example, be provided in the form of one or more contact pins and/or curved conductors. Moreover, the conducting element can include, for example, on a side of the base body and/or electrical bushing facing the internal space or on a side of the base body and/or electrical bushing facing the external space or accessible from the external space, one or more connecting contacts, for example one or more plug-in connectors, for example one or more connecting contacts, which project from the base body or can be electrically contacted through other means from the internal space and/or the external space. The conducting element can, for example on the side of the base body facing the internal space, end flush with the base body and/or project from the base body into the external space or be connected to another element. Regardless of the design of the inside, this applies just as well to the side of the base body facing the external space. The at least one conducting element can be electrically connected within the base body and/or on a side of the base body that faces the internal space and/or on a side of the base body that faces the external space, to one or more conductor elements. For example, one or more wires can be provided. The at least one conductor element can be manufactured, for example, fully or in part from at least one metallic material selected from the group consisting of: platinum; a platinum alloy; iridium; niobium; molybdenum; titanium; a titanium alloy; tantalum; a tantalum alloy; tungsten; a tungsten alloy; stainless steel; a cobalt-chromium alloy; gold or a gold alloy; silver; a silver alloy; copper; a copper alloy or aluminum or an aluminum alloy. Combinations of the specified materials and/or other materials are feasible just as well.

The at least one conducting element can establish the electrically conductive connection between the internal space and the external space in a variety of ways. For example, the conducting element can extend from at least one section of the conducting element that is arranged on the side of the base body facing the internal space to at least one section of the conducting element arranged on the side facing the external space or accessible from the external space. However, other arrangements are also feasible as a matter of principle. Accordingly, the conducting element can just as well include a plurality of partial conducting elements that are connected to each other in an electrically conducting manner. Moreover, the conducting element can extend into the internal space and/or the external space. For example, the conducting element can include at least one region that is arranged in the internal space and/or at least one region that is arranged in the external space, whereby the regions can, for example, be electrically connected to each other.

The electrically insulating base body can support, as a bearing, and/or surround, at least in part, for example, the at least one conducting element. For example, the at least one conducting element can be embedded in the base body fully or partly, for example in a firmly bonded manner. The at least one material of the base body should, in one embodiment, be biocompatible, as illustrated above, and should have sufficiently high insulation resistance. It has proven to be advantageous for the base body according to one embodiment to include at least one ceramic material or to consist of at least one ceramic material. In one embodiment, the base body includes one or more materials selected from the group consisting of: aluminum oxide (Al₂O₃), zirconium dioxide (ZrO₂), aluminum oxide-toughened zirconium oxide (ZTA), zirconium oxide-toughened aluminum oxide (ZTA-Zirconia Toughened Aluminum-Al₂O₃/ZrO₂), yttrium-toughened zirconium oxide (Y-TZP), aluminum nitride (AlN), magnesium oxide (MgO), piezoceramic materials, barium(Zr, Ti) oxide, barium(CE, Ti) oxide, and sodium-potassium-niobate.

With regard to possible refinements of the cermet and/or metal materials and/or components that are used, reference shall be made to the embodiments specified above. Combinations of multiple possibilities specified above are conceivable as well. In this context, ZTA shall be understood to mean zirconium-toughened alumina (Zirkonia Toughened Alumina), that is, a material, in which zirconium oxide is embedded in an aluminum oxide matrix, for example 10-30% by volume zirconium dioxide in an aluminum oxide matrix. In this context, ATZ shall be understood to mean alumina-toughened zirconia, that is, a material, in which aluminum oxide is embedded in a zirconium oxide matrix, for example at a fraction of 10-30% by volume. Y-TZP shall be understood to mean yttrium-toughened zirconium oxide, that is, zirconium oxide comprising an yttrium fraction. KNN means potassium-sodium niobate.

The base body can, for example, be made fully or partly from one or more sinterable materials, for example, from one or more ceramic-based sinterable materials. The conducting element or elements can fully or partly be made of one or more cermet-based sinterable materials. Moreover, the at least one conducting element can also, as mentioned above, include one or more additional conductors, for example one or more metallic conductors with no ceramic fraction.

In the scope of one embodiment, “cermet” shall refer to a composite material made of one or more ceramic materials in at least one metallic matrix or a composite material made of one or more metallic materials in at least one ceramic matrix. For production of a cermet, for example, a mixture of at least one ceramic powder and at least one metallic powder can be used to which, for example, at least one binding agent and, if applicable, at least one solvent can be added. The ceramic powder or powders of the cermet, in one embodiment, have a mean grain size of less than 10 μm, for example, less than 5 μm, and for example, less than 3 μm. The metallic powder or powders of the cermet, for example, have a mean grain size of less than 15 μm, for example, less than 10 μm, and for example, less than 5 μm. For production of a base body, for example, at least one ceramic powder can be used to which, for example, at least one binding agent and, if applicable, at least one solvent can be added. In this context, the ceramic powder or powders of the base body for example, has/have a mean grain size of less than 10 μm (1 μm corresponds to 1*10-6 m), for example, less than 5 μm, and for example, less than 3 μm. For example, the median value or the d50 value of the grain size distribution is considered to be the mean grain size in this context. The d50 value corresponds to the value at which 50 percent of the grains of the ceramic powder and/or metallic powder are finer and 50% are coarser than the d50 value.”

Generally, cermets are characterized by their particularly high toughness and wear resistance. The “cermets” and/or “cermet-containing” substances can, for example, be or include cutting materials related to hard metals which can dispense with tungsten carbide as the hard substance and can be produced, for example, by a powder metallurgical route. A sintering process for cermets and/or the cermet-containing bearing element can proceed, for example, alike a process for homogeneous powders except that, at identical compression force, the metal is usually compacted more strongly than the ceramic material. Compared to sintered hard metals, the cermet-containing conducting element usually illustrates higher resistance to thermal shock and oxidation. As explained above, the ceramic components can include, for example, at least one of the following materials: aluminum oxide (Al₂O₃), zirconium dioxide (ZrO₂), aluminum oxide-toughened zirconium oxide (ZTA), zirconium oxide-toughened aluminum oxide (ZTA-Zirconia Toughened Aluminum-Al₂O₃/ZrO₂), yttrium-toughened zirconium oxide (Y-TZP), aluminum nitride (AlN), magnesium oxide (MgO), piezoceramic materials, barium(Zr, Ti) oxide, barium(CE, Ti) oxide, and sodium-potassium-niobate. The at least one metallic component can include, for example, at least one of the following metals and/or an alloy based on at least one of the following metals: platinum, a platinum alloy, iridium, niobium, molybdenum, titanium, a titanium alloy, cobalt, zirconium, chromium, tantalum, a tantalum alloy, tungsten, a tungsten alloy.

In the scope of one embodiment, a ceramic manufacturing method shall be understood to mean a procedure that includes at least one sintering process of at least one insulating and/or at least one electrically conductive material, for example, at least one ceramic material. As shall be explained in more detail below, said ceramic manufacturing method can, for example, include a forming for the manufacture of at least one form body, for example one ceramic green compact and/or at least one ceramic brown compact.

In the scope of one embodiment, a sintering or a sintering process shall generally be understood to mean a procedure for the manufacture of materials or work-pieces, in which powdered, for example, fine-grained, ceramic and/or metallic substances are heated and connected in the process. This process can proceed without applying external pressure onto the substance to be heated or can, for example, proceed under elevated pressure onto the substance to be heated, for example under a pressure of at least 2 bar, for example, higher pressures, for example pressures of at least 10 bar, for example, at least 100 bar, or even at least 1000 bar. The process can proceed, for example, fully or partly, at temperatures below the melting temperature of the powdered materials, for example at temperatures of 700° C. to 1400° C. The process can be carried out, for example, fully or partly, in a tool and/or a mold such that a forming step can be associated with the sintering process. Aside from the powdered materials, a starting material for the sintering process can include further materials, for example one or more binding agents and/or one or more solvents. The sintering process can proceed in one or more steps, whereby additional steps can precede the sintering process, for example one or more forming steps and/or one or more debinding steps.

The electrical bushing according to one embodiment can be manufactured in a method comprising the following steps:
a. manufacturing the at least one base body and introducing the at least one conducting element into the base body in non-sintered or pre-sintered condition;
b. joint sintering of the base body and conducting element.

Accordingly, a sintered condition is understood to mean a condition of a work-piece, in which the work-piece has already undergone one or more steps of sintering. Accordingly, a non-sintered condition is understood to mean a condition, in which the work-piece has not yet undergone a step of sintering. In this condition, the work-piece can for example be present as a green compact. A pre-sintered condition—also called a partially sintered condition—shall be understood to mean a condition, in which the work-piece has already undergone at least one step of sintering or at least one part of a step of sintering, in which the work-piece has not been sintered completely though, that is, in which the work-piece can still be sintered further and can be sintered further through one or more steps of sintering. In this condition, the work-piece can be present, for example, as at least partial green compact, as brown compact or already as a ceramic body.

A method can be used, for example, in the manufacture of the at least one conducting element and/or optionally in the manufacture of the at least one base body, in which at least one green compact is manufactured first, subsequently at least one brown compact is manufactured from said green compact, and subsequently the finished work-piece is manufactured from said brown compact through at least one sintering step. In this context, separate green compacts and/or separate brown compacts can be manufactured for the conducting element and the base body and can be connected subsequently. Alternatively, one or more common green compacts and/or brown compacts can be produced for the base body and the conducting element. Alternatively again, separate green compacts can be produced first, said green compacts can then be connected, and subsequently a common brown compact can be produced from the connected green compact. In general, a green compact shall be understood to mean a preform body of a work-piece which includes the starting material, for example the at least one ceramic and/or metallic powder, as well as, if applicable, one or more binding materials. A brown compact shall be understood to mean a preform body which is generated from the green compact through at least one debinding step, for example at least one thermal and/or chemical debinding step, whereby the at least one binding agent and/or the at least one solvent is/are removed, at least partly, from the pre-form body in the debinding step.

The sintering process, for example, of a cermet, but of the base body just as well, for example, can proceed comparable to a sintering process that is commonly used for homogeneous powders. For example, the material can be compacted in the sintering process at high temperature and, if applicable, high pressure such that the cermet is virtually sealed tight or has no more than closed porosity. Usually, cermets are characterized by their particularly high toughness and wear resistance. Compared to sintered hard metals, a cermet-containing transmission element usually has a higher thermal shock and oxidation resistance and usually a thermal expansion coefficient that is matched to a surrounding insulator.

For the bushing according to one embodiment, the at least one ceramic component of the cermet can include, for example, at least one of the following materials: aluminum oxide (Al₂O₃), zirconium dioxide (ZrO₂), aluminum oxide-toughened zirconium oxide (ZTA), zirconium oxide-toughened aluminum oxide (ZTA-Zirconia Toughened Aluminum-Al₂O₃/ZrO₂), yttrium-toughened zirconium oxide (Y-TZP), aluminum nitride (AlN), magnesium oxide (MgO), piezoceramic materials, barium(Zr, Ti) oxide, barium(CE, Ti) oxide, and sodium-potassium-niobate.

For the bushing according to one embodiment, the at least one metallic component of the cermet can include, for example, at least one of the following metals and/or an alloy based on at least one of the following metals: platinum, iridium, niobium, molybdenum, tantalum, tungsten, titanium, cobalt or zirconium. An electrically conductive connection is usually established in the cermet when the metal content exceeds the so-called percolation threshold at which the metal particles in the sintered cermet are connected to each other, at least in spots, such that electrical conduction is enabled. For this purpose, experience tells that the metal content should be 25% by volume and more, for example, 32% by volume, for example, more than 38% by volume, depending on which materials have been selected.

In the scope of one embodiment, the terms, “including a cermet,” “comprising a cermet,” and “cermet-containing”, are used synonymously. Accordingly, the terms refer to the property of an element, being that the element contains cermet. This meaning also includes the variant of an embodiment in that the element, for example the conducting element, consists of a cermet, that is, is fully made of a cermet.

In one embodiment, both the at least one conducting element and the base body can include one or more components which are or can be manufactured in a sintering procedure, or the at least one conducting element and the base body are or can both be manufactured in a sintering procedure. For example, the base body and the conducting element are or can be manufactured in a co-sintering procedure, that is, a procedure of simultaneous sintering of these elements. For example, the conducting element and the base body each can include one or more ceramic components that are manufactured, and compacted, in the scope of at least one sintering procedure.

For example, a base body green compact can be manufactured from an insulating composition of materials. This can proceed, for example, by compressing the composition of materials in a mold. In this context, the insulating composition of materials is a powder mass, in which the powder particles illustrate at least minimal cohesion. In this context, the manufacture of a green compact proceeds, for example, through compressing powder masses and/or through forming followed by drying.

Said procedural steps can also be utilized to form at least one cermet-containing conducting element green compact. In this context, one embodiment can provide that the powder, which is compressed to form the conducting element green compact, is cermet-containing or consists of a cermet or includes at least one starting material for a cermet. Subsequently, the two green compacts—the base body green compact and the conducting element green compact—can be combined. The manufacture of the conducting element green compact and of the base body green compact can just as well proceed simultaneously, for example, by multi-component injection molding, co-extrusion, etc., such that there is no longer a need to connect them subsequently.

While the green compacts are being sintered, they are in one embodiment subjected to a heat treatment below the melting temperature of the powder particles of the green compact. This usually leads to compaction of the material and thus to ensuing substantial reduction of the porosity and volume of the green compacts. Accordingly, one particularity of the method according to one embodiment is that the base body and the conducting element can be sintered jointly. Accordingly, there is no longer a need to connect the two elements subsequently.

Through the sintering, the conducting element becomes connected to the base body in a positive fit-type and/or non-positive fit-type and/or firmly bonded manner. In one embodiment, this achieves hermetic integration of the conducting element into the base body. In one embodiment, there is no longer a need for subsequent soldering or welding of the conducting element into the base body. Rather, a hermetically sealing connection between the base body and the conducting element is attained through the joint sintering and utilization of a cermet-containing green compact.

One refinement of the method according to an embodiment is characterized in that the sintering includes only partial sintering of the at least one optional base body green compact, whereby said partial sintering can effect and/or include, for example, the debinding step described above. IN one embodiment, the green compact is heat-treated in the scope of said partial sintering. This is usually already associated with some shrinkage of the volume of the green compact. However, the volume of the green compact has not yet reached its final state. Rather, another heat treatment is usually needed—a final sintering—in which the green compact(s) is/are shrunk to its/their final size. In the scope of said variant of an embodiment, the green compact is sintered only partly in order to attain a certain stability to render the green compact easier to handle.

The starting material used for producing at least one conducting element green compact and/or at least one base body green compact can, for example, be a dry powder or include a dry powder, whereby the dry powder is compressed in the dry state into a green compact and illustrates sufficient adhesion to maintain its compressed green compact shape. However, optionally, the starting material can include one or more further components in addition to the at least one powder, for example, as mentioned above, one or more binding agents and/or one or more solvents. Said binding agents and/or solvents, for example organic and/or inorganic binding agents and/or solvents, are generally known to the person skilled in the art, and are commercially available, for example. The starting material can, for example, include one or more slurries or be a slurry. In the scope of one embodiment, a slurry is a suspension of particles of a powder made of one or more materials in a liquid binding agent, and, if applicable, in a water-based or organic binding agent. A slurry has a high viscosity and can easily be shaped into a green compact without the application of high pressure.

In the case of green compacts made from slurries, the sintering process, which is generally carried out below the melting temperature of the ceramic, cermet or metal materials that are used, but in individual cases can also be carried out just above the melting temperature of the lower melting component of a multi-component mixture, this usually being the metal component, leads to the binding agent slowly diffusing from the slurry. Overly rapid heating leads to a rapid increase of the volume of the binding agent by transition to the gas phase and destruction of the green compact or formation of undesired defects in the work-piece.

Thermoplastic and duroplastic polymers, waxes, thermogelling substances and/or surface-active substances, for example, can be used as binding agent—also called binder. In this context, these can be used alone or as binding agent mixtures of multiple components of this type. If individual elements or all elements of the electrical bushing (for example the at least one base body green compact and/or the at least one conducting element green compact) are produced in the scope of an extrusion procedure, the composition of the binding agent should be such that the line of the elements extruded through the nozzle is sufficiently stable in shape for the shape defined by the nozzle to be maintained easily. Suitable binders, also called binding agents, are known to the person skilled in the art.

In contrast, the conducting element according to the prior art usually is a metal wire. A conducting element provided according to one embodiment with at least one cermet can be connected easily to other structural elements, since it is a composite of metal and ceramic material. Accordingly, green compacts of both the conducting element and other structural elements, for example in the base body, can be produced and subsequently subjected to a sintering process. Alternatively or in addition, at least one common green compact for multiple structural elements can be manufactured just as well. The resulting electrical bushing is not only particularly biocompatible and durable, but also possesses good hermetic sealing properties. Thus, usually no fissures or connecting sites still to be soldered arise between the conducting element and the base body. Rather, sintering results in the base body and the conducting element becoming connected. One variant of an embodiment, therefore provides the at least one conducting element to consist of a cermet. In this variant of an embodiment, the conducting element includes not only components made of cermet, but is fully made of a cermet.

There are multiple ways of connecting the electrical bushing to the housing. These options can also be combined with each other. Accordingly, one option is to directly connect the electrical bushing and/or the base body to the housing, for example in a non-positive fit-type manner and/or positive fit-type manner and/or firmly bonded manner. For example, a firmly bonded connection between the contact region and an internal side and/or an external side of the housing and/or a rim of the housing facing in the direction of the housing opening can be implemented, for example, at least one soldered connection. In order to promote wetting of the electrical bushing, for example, of the ceramic base body of the electrical bushing, with solder, at least one metallization of the base body can be provided as contact region, for example a metallization that is applied through at least one physical vapor deposition procedure, for example a sputtering procedure. Accordingly, the base body can include a metallization that covers the base body, for example, parts thereof, whereby the base body can be connected to the housing in a firmly bonded manner by means of the metallization. Said metallization can, for example, include at least one metal selected from the group consisting of gold, titanium and chromium and/or at least one combination and/or at least one multiple layer comprising one or more of said metals. In one possible embodiment, the contact region can include a cermet and/or be made from a cermet.

Aside from the firmly bonded connection, the base body and the housing can be connected in a variety of ways by means of the contact region, whereby these ways can also be combined as a general rule. Accordingly, this connecting may involve the use of one or more non-positive fit-type and/or positive fit-type connection techniques.

The base body of the electrical bushing can be connected to the housing by means of the contact region in a variety of ways. For example, the base body and/or the contact region can be placed on the housing proceeding from the internal space or from the external space, for example if at least one physical dimension of the base body is larger than the corresponding dimension of the housing opening. Alternatively or in addition, the base body and/or the contact region can just as well be inserted fully or partly into the housing opening and/or project into the housing opening.

As before, the base body and/or the contact region and/or the centering element can be provided such that the base body and/or the contact region and/or the centering element can be unambiguously positioned to be oriented towards the housing, for example oriented in self-centering manner towards the at least one housing opening. This can be effected, as before, in that at least one part of the housing and/or the centering element engages the housing opening in a perfect fit or with little tolerance, for example with a tolerance of less than 0.5 mm, for example, less than 0.2 mm, and for example, less than 0.1 mm.

Moreover, the base body and/or the contact region and/or the housing can include at least one fastening profile. As a general rule, a fastening profile shall be understood to mean any profile that deviates from a planar resting surface and supports the fastening of the electrical bushing on the housing. Said fastening profile can, for example, be provided such that the housing partly surrounds the base body or includes at least two contact surfaces to the base body that are arranged at an angle to each other. Accordingly, for example an angular or rounded U-shaped profile can be provided, whereby the base body, for example, can be embedded between the arms of the U or project into the space between them.

Another embodiment is characterized in that the electrical bushing further includes at least one filter element, for example, a filter element selected from the group consisting of: a high-pass filter, a low-pass filter, a band-pass filter.

According to another aspect, proposed is an implantable medical device having the features described above. Features and details that were described in the context of the electrical bushing and/or any of the methods shall also apply in relation to the implantable medical device, and vice versa. Moreover, the implantable medical device can further include, for example, at least one supply lead, which is also called “lead” or “leads” in English and can be set-up to form an electrical connection to the electrical bushing, for example an electrical plug connection. The lead can, for example, comprise at least one plug element, for example at least one male and/or at least one female plug element, which can form an electrical plug-in connection with the plug connection element of the electrical bushing. This can, for example, be at least one male plug element which can be plugged into the at least one plug connection element, for example at least one plug element according to the IS-1 (ISO 5841-3), DF-1 (ISO 11318:1993) and/or IS-4 standard.

As illustrated, the housing includes the at least one housing opening which basically can take any shape such as, for example, a round, oval or polygonal shape. The housing can, for example, be assembled from multiple housing parts, for example from at least two housing shells, whereby, for example, the housing opening is accommodated in one of the housing parts or in at least two of the housing parts, for example in the form of cut-outs in the housing parts which complement each other to form the housing opening when the housing parts are joined. The housing can, for example, be manufactured fully or in part from a metallic material, in on embodiment from titanium or a titanium alloy. Alternatively or in addition, any other materials can be used just as well, for example one or more of the materials specified above with regard to the frame element.

At least one electrical connection between at least one internal space of the housing and at least one external space is established through the electrical bushing. The housing opening can be closed, for example, and as specified above, in a hermetically sealed manner by the electrical bushing.

The proposed electrical bushing and the implantable medical device according to embodiments provide a large number of advantages as compared to known devices of the specified type. Accordingly, a cost-efficient manufacturing method can be implemented which features high process reliability and low waste production at the same time. For example, according to one embodiment, the number of boundary surfaces can be reduced which allows the potential of errors to be generally reduced. The boundary surfaces being reduced reduces, for example, the ingress of moisture or body fluid.

Simultaneously, the use of ceramic materials allows high mechanical stability and strong sealing against moisture, for example, body fluid, to be implemented. Accordingly, the proposed bushings have a long service life.

As part of the investigations, the following exemplary embodiment of an electrical bushing according to one embodiment would be produced: In the first step, a cermet mass is produced from platinum (Pt) and aluminum oxide (Al2O3) containing 10% zirconium dioxide (ZrO2). The following starting materials are used for this purpose:
40 vol. % Pt powder with a mean grain size of 10 μm, and
60 vol. % Al2O3/ZrO2 powder with a relative ZrO2 content of 10% and a mean grain size of 1 μm.

The two components were mixed, water and a binding agent were added, and the sample was homogenized through a kneading process. Analogous to the first step, a ceramic mass is produced in a second step from a powder with an Al2O3 content of 90% and a ZrO2 content of 10%. The mean grain size was approx. 1 μm. As before, water and a binding agent were added to the ceramic powder and the sample was homogenized. In a third step, the ceramic mass made of aluminum oxide with a 10% zirconium dioxide content produced in step two was converted to the shape of a base body. A cermet body, which was made from the cermet mass produced in step 1 and contained a mixture of platinum powder and aluminum oxide with a zirconium dioxide content of 10%, was introduced as green compact into an opening in the base body green compact. Subsequently, the ceramic mass was compacted in the mold. Then the cermet and the ceramic component were subjected to debinding at 500° C. and the sintering was finished at 1650° C.

The housing or an element of the housing, such as the bushing support to be illustrated in more detail below, can include titanium or a titanium alloy or consist of titanium or a titanium alloy. In this case, one variant of an embodiment of the electrical bushing is characterized in that the base body can be connected to a titanium-comprising housing in a firmly bonded manner by means of the contact region. Appropriate selection of the base body allows a firmly bonded connection to a titanium-containing material to be established. The selection of available base body materials is limited by the base body, on the one hand, having to be electrically insulating. On the other hand, its use in a medical device requires that the base body consists of a biocompatible material. In order to enable the firmly bonded connection of the base body to the housing by means of the contact region, the base body can be doped with metal in the region of the contact region. Alternatively or in addition, it is feasible to apply solder materials or solder pastes. Said materials can be applied by imprinting.

One variant of an embodiment is characterized in that the contact region can be connected to the housing through a soldered connection or sintered connection. Soldering is a thermal procedure for joining materials in a firmly bonded manner, whereby a liquid phase arises through melting of a solder or through diffusion at the boundaries. The liquidus temperature of the basic materials is not reached in the process. Accordingly, the contact region can be provided as a solder. If applicable, a solder ring is arranged between the contact region and the housing such that the contact region only needs to be capable of engaging in a firmly bonded connection to the solder ring and, mediated thus, to the housing. Alternatively or in addition, it has proven to be advantageous in one embodiment to provide the contact region such that it and the housing can engage in a sintered connection. This allows the contact region to be formed, for example, as a brown compact that establishes a sintered connection either directly to the housing in the scope of a step of sintering. Alternatively, it is feasible to paste or imprint the corresponding slurry, such as a ceramic slurry for example, which is then used in the scope of a step of sintering as a kind of bonding agent in order to connect the contact region to the housing in a firmly bonded manner.

One embodiment of the electrical bushing is characterized in that the contact region is and/or contains a metallic coating—also called metallization—on the base body. As illustrated, the contact region, or at least regions thereof, overlaps an opening in the housing. One embodiment provides the electrical bushing to be connected to the housing directly and in a firmly bonded manner. As illustrated above, it is advantageous in one embodiment for the base body to be made from an insulating material, for example a ceramic material. Some of the ceramic materials listed above do not allows for direct contacting of the ceramic material as such and the metal. Accordingly, one embodiment provides for a contact region. Said contact region can be a metallic coating on the base body in the variant of an embodiment described here. Said metallic coating then ensures that a firmly bonded connection is established between the base body and the housing in the scope of a soldering process. A corresponding metallic coating can be applied by vapor deposition, sputtering or imprinting. In this context, the metallic coating is to include metals that facilitate, for example, a lasting and stable and firmly bonded connection to a housing made of titanium to be established. This concerns metals from the group of: silver, gold or brass, for example, an alloy of any of said metals. The, at least partial, utilization of any of said metals in the metallic coating enables a hermetically tight connection between base body and housing to be established. Further metals for the metallic coating—also called metallization—are listed above.

In one variant of an embodiment, the electrical bushing is structured such that the area claimed by the electrical bushing is larger than the area of the opening in the housing—also called housing opening—above which the electrical bushing is to be installed. In this case, the electrical bushing therefore covers the opening in the housing fully. In this type of refinements, it has proven advantageous for the contact region to be arranged on an underside of the base body that faces towards the housing. In the scope of the manufacture of the active implantable device, the electrical bushing can be arranged on the housing in a manner such that the opening in the housing is fully covered. Since the contact region is arranged on the underside of the base body, the base body is situated in extensive contact with the rims of the opening of the housing. Such extensive contact ensures the hermetical sealing of the medical device and is easy to implement.

In one refinement, the base body is provided as a flat disc, for example, as a flat ceramic disc. In said variant of an embodiment, the base body has a cross-section that is shaped like a rectangle. Corresponding base bodies are easy to manufacture. Said specific design also allows to dispense with a flange and to solder the electrical bushing directly to the housing. One other advantage of the bushing according to one embodiment is that it can be manufactured using simple methods which might well be based on known procedures.

Another refinement is characterized in that the base body includes at least one centering element, whereby the at least one centering element includes a shape that is complementary, at least in part, to the shape of an opening in the housing in order to enable positioning of the electrical bushing in the housing. As illustrated, the electrical bushing covers a housing opening in the housing. A centering element can be arranged on the base body in order to ensure the positioning of the electrical bushing on the housing. Said centering element can be arranged, for example, on an underside of the base body that is provided to be shaped like a disc. The centering element can be a ring or elements provided to be pin-like. These must be designed such that they project sufficiently far into the opening of the housing in order to enable a positioning of the electrical bushing in the range of the acceptable error tolerances. The, at least partly, complementary shape of the centering elements can be afforded in one of two ways. For one, the shape of the cross-section of the opening can define a corresponding shape of the centering elements. Accordingly, the opening in the housing can be produced, for example, in the scope of a punching process, in which parts of the housing rims are bent into the inside of the housing. In this context, it has proven to be advantageous that the at least one centering element is designed such that the shape is complementary to the arc-like shape of the punch made in the housing. Moreover, the projection of the opening in the plane of the opening can have a round, oval, rectangular or any other shape. As before, it has proven to be advantageous in one embodiment for the at least one centering element to have a complementary shape, at least in part, to said projected shape of the opening. Depending on the material selected for the base body and/or depending on the manufacturing process selected for the electrical bushing, it can be advantageous for the centering element to be provided as a closed curve that is arranged on an underside of the base body. Alternatively, a plurality of centering elements can be arranged on the base body and thus provide for a positive fit-type seating of the electrical bushing in the opening, at least over regions thereof. In another embodiment, the base body and the centering element can be provided to be made from the same material.

The contact region, or at least regions thereof, surrounds the centering element. As illustrated, the at least one centering element is to penetrate into the opening of the housing. Depending on the design of the centering element and of the opening, it has proven to be advantageous in one embodiment for the contact region not to be arranged on the centering element, but rather to cover alternative regions of the base body of the electrical bushing. Alternatively, it is also feasible that the contact region covers at least certain parts of the centering element. In another embodiment, the base body and the centering element can be provided to be the same part and made from the same material. In this embodiment, the base body and the centering element are made from the same ceramic material. This can be implemented, for example, by producing the base body and the centering element in a common green compact.

Another refinement of the electrical bushing is characterized in that the base body and the at least one conducting element include a firmly bonded sintered connection, for example, in that the at least one conducting element is made from a cermet material that is sintered jointly with the base body.

An electrical bushing is described in the scope of one embodiment of the present application that is characterized in that the base body includes a contact region by means of which the electrical bushing can be connected to a housing of a medical device in a firmly bonded manner. A bushing support, for example, can be part of the housing of the medical device. Accordingly, one embodiment also relates to a bushing support for use in the housing of an active implantable medical device having at least one electrical bushing according to at least one of the embodiments described above, and a channel element, whereby the channel element is set up to establish, through the bushing support, at least one gas-permeable connection between an upper region of the bushing support and a lower region.

The hermetical sealing of medical devices is of crucial significance. The scope of the manufacture of a medical device includes testing of all components for hermetical sealing. Due to their geometric size, the testing, for example, of electrical bushings is associated with some difficulty. In order to reduce said difficulty, it has proven to be advantageous in one embodiment to use a bushing support. An individual electrical bushing or a plurality of electrical bushings can be installed on said bushing support. Subsequently, the hermetical sealing of the bushing support bearing the—in particular multiple—electrical bushing(s) is tested. If the bushing support passes the respective test in the scope of quality assurance, the bushing support is then connected to a pocket-like housing part and thus forms the housing of the medical device. The bushing support can cover, like a lid, an opening that is arranged in the housing part shaped like a pocket. Aside from the test of the electrical bushing mentioned above, it is to be seen as another advantage that corresponding bushing supports generally are made of a metal that is identical to the metal of the remaining part of the housing. This is titanium in one embodiment. Welding the housing part made of titanium to the bushing support made of titanium can be ensured easily and in a controlled manner. Accordingly, one embodiment described here includes that the base body of the electrical bushing includes a contact region, whereby the base body can be connected to the bushing support of the housing in a firmly bonded manner by means of the contact region. The bushing support differs from known flanges by its function described here and by its size.

The bushing support described according to one embodiment can include a channel element. Said channel element serves as a type of feedthrough. The scope of the test of hermetical sealing involves guiding helium through the channel element underneath the electrical bushings. A helium leak tester is then used to search for possible leaks in the electrical bushings. After welding the bushing support to the housing part to form the housing, said channel element is further utilized to guide an inert gas, such as nitrogen, into the inside of the housing. Subsequently, the channel element is welded shut in a firmly bonded manner.

The object specified above is also met by a housing as disclosed herein. One aspect relates to a housing for an active implantable medical device, whereby the housing includes at least one electrically insulating bushing, whereby the electrical bushing includes at least one electrically insulating base body and at least one electrical conducting element, whereby the conducting element is set up to establish, through the base body, at least one electrically conductive connection between an internal space of the housing and an external space, whereby the conducting element is hermetically sealed with respect to the base body, whereby the at least one conducting element includes at least one cermet. One embodiment provides the base body to include a contact region, whereby the base body is connected to the housing in a firmly bonded manner by means of the contact region. Features and details that are described in the context of the electrical bushing shall obviously also apply accordingly in relation to the housing according to one embodiment, and vice versa.

The special feature of the housing disclosed here is that the base body of the electrical bushing is connected to the housing directly and in a directly firmly bonded manner. The electrical bushing is therefore connected to the housing free of a frame. This dispenses with at least one firmly bonded connection seam as would be present between the base body and the flange according to the prior art. A corresponding reduction of the number of connection seams simultaneously reduces the proneness to failure of the housing and/or of the active implantable medical device.

Moreover, an active implantable medical device having at least one electrical bushing according to any one of the variants of embodiments described above is claimed in the patent application. One embodiment also claims an active implantable medical device having at least one bushing support according to any one of the variants of embodiments described above, whereby, for example, the bushing support comprises a channel element, whereby the channel element is set up to establish, through the bushing support, at least one gas-permeable connection between an upper region of the bushing support and a lower region. One embodiment also claims an active implantable medical device having at least one housing according to any one of the variants of embodiments described above.

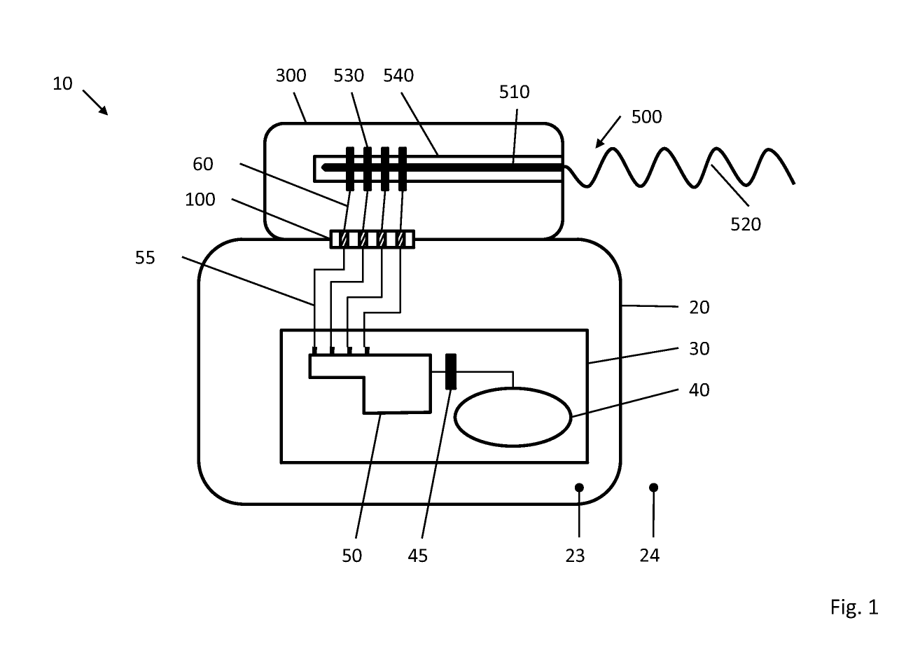

FIG. 1 illustrates an active implantable medical device 10. The electrical bushing 100 is part of said device 10. Device 10 includes a housing 20. A circuit board 30 is arranged inside the housing 20 and has an electronics unit 50 installed on it. A battery 40 supplies the needed electrical energy to the electronics unit 50. A capacitor 45 can be used to store the pulse energies required for implantable defibrillators. The electrical bushing 100 according to one embodiment is integrated into the housing 20 in such a manner that the electronics unit 50 is sealed-off hermetically from the surroundings. The electrical bushing 100 according to one embodiment allows helium leak rates of less than 1×10⁻⁹ atm*cm³/sec to be attained. Moreover, it withstands cleaning and sterilization processes.

The individual channels of the electronics unit 50 are connected to the individual conducting elements 110 of the electrical bushing 100 through internal connecting elements 55. Said internal connecting elements 55 can be wires and/or sintered elements that are connected directly to the electronics unit 50. In case the implantable medical device 10 is a cardiac pacemaker, the electronics unit 50 is to trigger pulses which are conducted through a lead 500 to an electrode (not illustrated here) which in general is arranged to be situated right in the patient's heart muscle. In this location, the electrical pulse of the cardiac pacemaker can stimulate the heart muscle. The electrical bushing 100 is part of said lead that conducts the electrical pulse from the electronics unit 50 to the electrode. The actual lead 500 that is introduced into the patient's body includes a lead wire 520 that extends through parts of the patient and is connected to the electrode on its distal end. On the proximal end, the lead wire 520 is connected to a connector plug 510. Said connector plug 510 is supported, as in a bearing, in a receiving element 540. The receiving element 540 is part of a head part 300—also called header—that is connected to the housing 20 of the implantable device 10. In known implantable devices, said head part 300 is manufactured from a plastic material. Multiple connecting sockets 530 are arranged inside the receiving element 540 and establish a non-positive type- and/or positive type—contact to the connecting plug 510. In addition, the connecting sockets 530 are connected through external connecting elements 60 to the conducting elements 110 in the electrical bushing 100. On one inside within the housing 20, the conducting elements 110 are electrically connected through internal connecting elements 55 to the individual channels of the electronics unit 50 of the implantable device 10. Accordingly, an electrical pulse from the electronics unit 50 can be conducted through the internal connecting elements 55, through the conducting elements 110, the external connecting elements 60, and the connection socket 530 to the electrode and thus to the heart muscle.

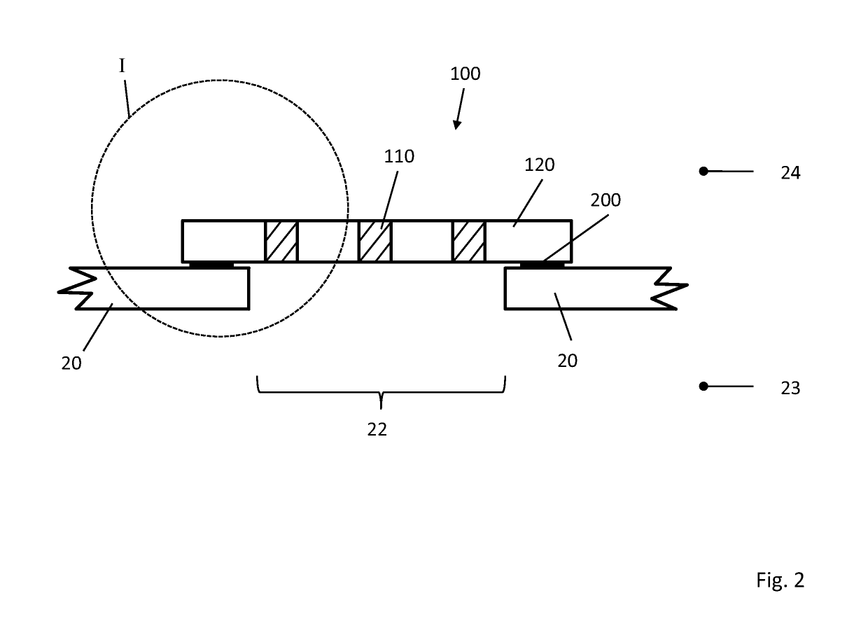

FIG. 2 illustrates the housing 20 and the electrical bushing 100 according to one embodiment. The electrical bushing 100 includes an electrically insulating base body 120 that is made, for example, from a ceramic material. Three electrical conducting elements 110 are connected to the base body 120 in a firmly bonded manner. Said conducting elements 110 extend through the base body 120. The purpose of the electrical conducting elements is to establish an electrically conductive connection between an internal space 23 of the housing 20 and an external space 24. The firmly bonded connection between the conducting element 110 and the base body 120 generates a hermetically sealed electrical bushing 100. The conducting elements 110 are made from a cermet in the exemplary embodiment illustrated. The special feature according to one embodiment is that the base body is connected directly and without intervening means to the housing 150.

The conducting elements 110 of the electrical bushing 100 are part of a conduction pathway through which, for example, electrical pulses are conducted from an electronics unit 50 that is arranged inside the housing 20 to an electrode that is arranged in the external space 24. In order to enable said bushing, the housing 20 includes an opening 22 that is roofed by the electrical bushing. The firmly bonded connection between the base body 120 and the housing 20 ensures the hermetical sealing of the active implantable medical device 10.

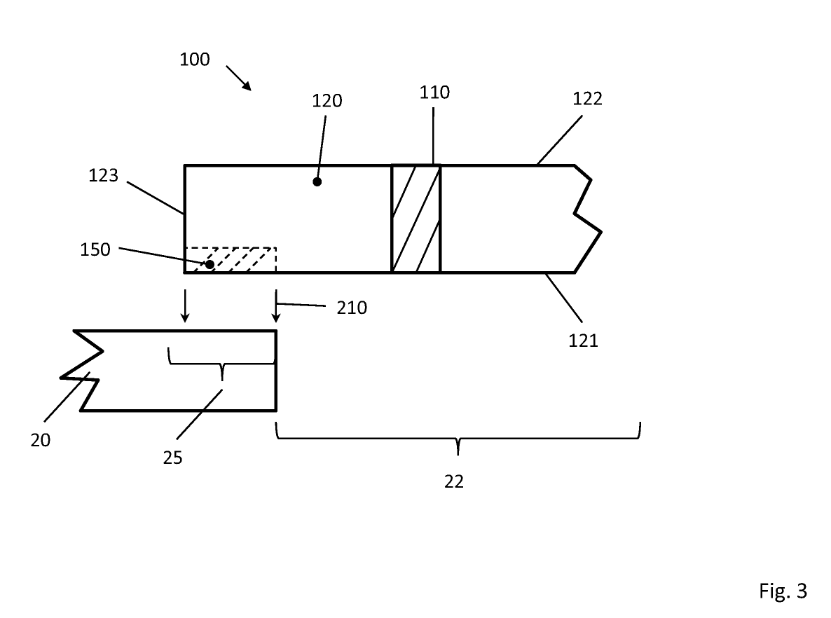

FIG. 3 illustrates a magnified detail of region I from FIG. 2. The electrical bushing 100 according to one embodiment is characterized in that the base body 120 includes a contact region 150. In the exemplary embodiment illustrated, the contact region is arranged on an external surface of the base body 120 which is provided to be disc-like. The contact region 150 is provided such that the base body can be connected to the housing 150 in a firmly bonded manner. The motion arrows 210 illustrate the act of placing the electrical bushing 100 onto a rim region 25 that surrounds the opening 22. A firmly bonded connection can be built up between the rim region 25 of the housing 20 and the contact region 150 of the electrical bushing 100. This can be effected, for example, through a soldering process. In order to enable the soldered connection between the base body 120 and the housing 20 to be established, the contact region 150 can be provided as a metallic coating. Said metallic coating on the base body 120 enables the firmly bonded connection to be established between a base body, which is made, for example, from a ceramic material, and a housing 20, which is, for example, made from titanium.

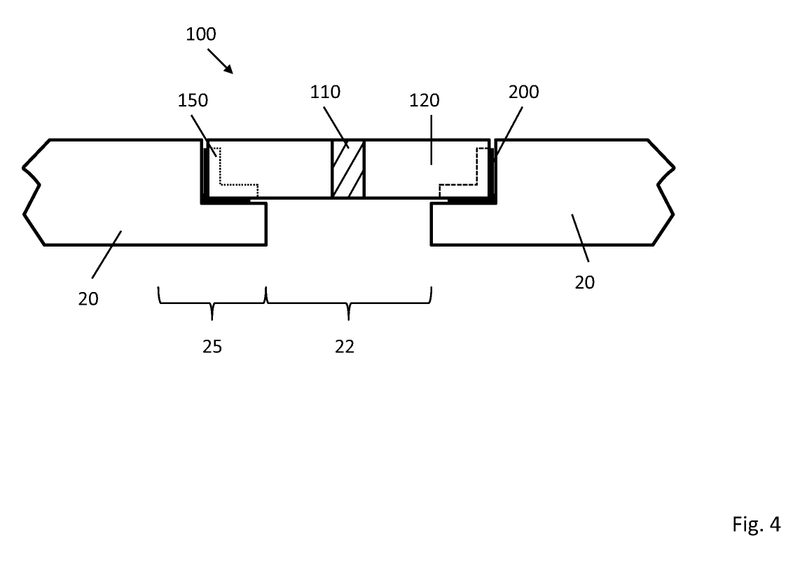

FIG. 4 illustrates another arrangement of the electrical bushing according to one embodiment in a housing 20. As before, the base body 120 is connected to the housing 20 in a direct and firmly bonded manner. No further element is arranged between the base body 120 and the housing 20. In contrast to the prior art, this constitutes a frame-less electrical bushing that is not provided with a collar-like frame that surrounds the base body. In the exemplary embodiment illustrated, the rim region 25 of the housing 20 has an L-shaped cross-section. Said L-shaped cross-section forms a kind of projection on which the base body 120 is supported. In the scope of the manufacturing process, a solder ring or a solder paste is arranged between the housing 20 and the electrical bushing 100 in such a manner that it supports the formation of the firmly bonded connection 200 between the base body 120 and the housing 20. In this context, the manufacturing process includes the following three steps:
Producing the housing 20 having the opening 22.
Placing a solder ring and/or a solder paste around the opening 22 in the rim region 25.
Placing the electrical bushing 100 onto the housing 20 (cf. FIGS. 2, 5, and 6) or at least partial insertion of the electrical bushing into a housing opening (cf. FIG. 4).
Thermal treatment of the system of electrical bushing 100 and housing 20 such that a firmly bonded connection 200 between the base body 120 and the housing 20 is formed.

For the firmly bonded connection 200 to be hermetically sealed, it has proven to be advantageous in one embodiment to place a weight onto the electrical bushing 100 in the scope of the thermal treatment in order to promote the formation of a connection between the materials of the contact region 150 in the base body 120 and the materials of the housing 20. The heat treatment can proceed, for example, in a vacuum furnace or similar facilities that are known to the person skilled in the art.

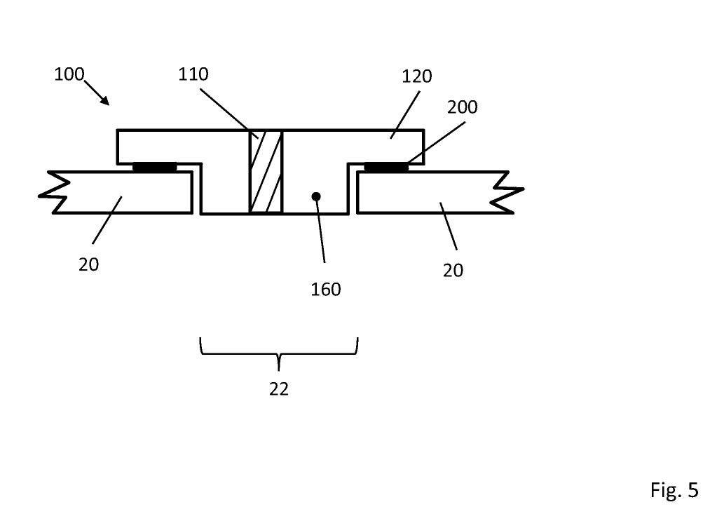

FIG. 5 illustrates another refinement of the housing 20 of the electrical bushing 100 according to one embodiment. Moreover, the electrical bushing 100 includes a centering element 160. Said centering element 160, at least regions thereof, projects into the opening 22 of the housing 20 and thus facilitates positioning of the electrical bushing 100 in the housing 20. According to one embodiment, the base body 120 and the centering element 160 are provided as a single part and are made of the same material. In the exemplary embodiment illustrated, the housing 20 is provided to be plate-shaped in the region of the housing opening 22. A cylinder-shaped housing opening 22 is provided in the housing 20. The centering element has a shape, at least over regions thereof, that is complementary to the opening 22 and is thus also provided to be cylinder-shaped. Correct positioning of the electrical bushing 100 in the opening 22 is easy to achieve during the installation. The desired positioning of the electrical bushing 100 is attained as soon as the centering element 160 is inserted into the opening 22. Accordingly, having the centering element 160 ensures, on the one hand, that the opening 22 is completely covered by the base body 120 and/or the electrical bushing 100. On the other hand, the centering element 160 helps to position the base body 120 such that the contact region 150 comes to rest in immediate spatial vicinity to the housing 20.

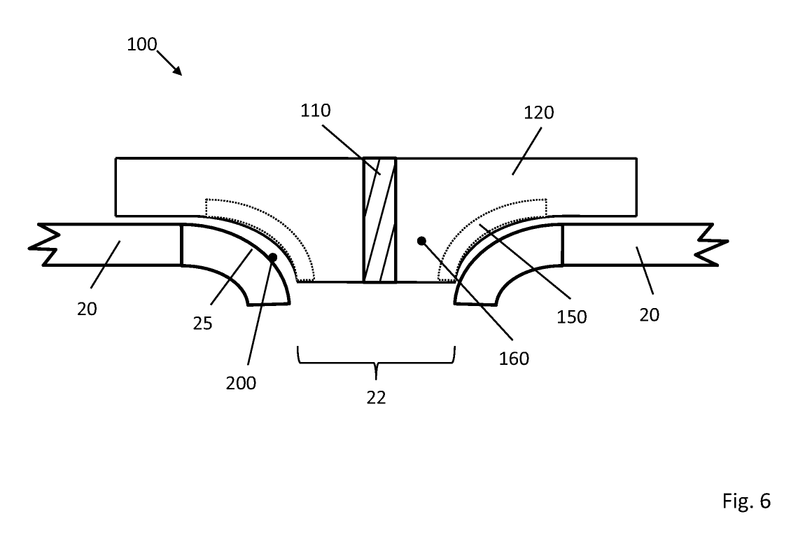

FIGS. 2 and 5 illustrate the contact region 150 each arranged on an underside 122 of the base body. In said exemplary embodiments, the electrical bushing is provided just on said underside 122 with a contact region that is connected to the housing 20 in a firmly bonded manner. FIG. 4 illustrates an electrical bushing 100 that includes a contact region 150 that is arranged both on an underside 121 and on an external side 123 of the base body 120. Both the arrangement and the design of the contact region 150 are therefore directly dependent on the type and design of the opening 22 and/or of the housing 20. This is emphasized in FIG. 6 as well.

The housing 20 in FIG. 6 includes an opening 22 that is bent in a funnel-like manner. As is emphasized by the cross-section through the housing 20 and the electrical bushing 100 in FIG. 6, the rims of the opening 22 are provided to be semicircular in shape. The centering element 160 has a shape that is complementary to said funnel-like opening 22. Accordingly, an internal side of the centering element 160—which ends in the underside of the base body 120—is provided to be arc-shaped. This allows the electrical bushing 100 to be positioned easily in the housing 20. In the exemplary embodiment illustrated, the contact region 150 includes both elements of the underside of the base body 120 and regions of the centering element 160. Said design of the electrical bushing and/or of the housing 20 enables an extensive firmly bonded connection to be established. In the scope of the manufacturing process, a solder ring can be placed on the arced rim region 25 of the opening 22. Subsequently, the electrical bushing having the centering element 160 is inserted into the solder ring and into the opening 22. A soldering process in a vacuum furnace involves a firmly bonded connection between the base body 120 and the housing 20 being established in the contact region 150.

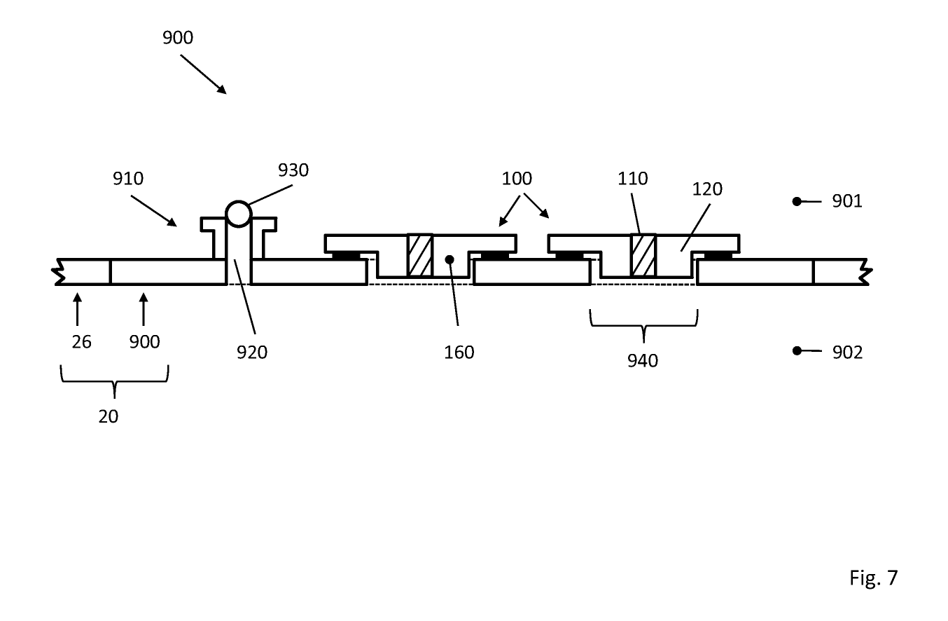

FIG. 7 illustrates a bushing support 900. The bushing support 900 is part of the housing 20. The bushing support 900 generally is made from the same material as a housing part 26 to which same is being connected in a firmly bonded manner in order to form the housing 20. The bushing support 900 must not be mistaken for a frame of the type that is arranged around the base body 120. Rather, the bushing support 900 is the foundation for at least one electrical bushing. Moreover, the bushing support 900 includes a channel element 110 in the exemplary embodiment illustrated. The rationale for having the bushing support is the desire to test whether or not the electrical bushing 100 is hermetically sealed. Since the geometrical size of the electrical bushing 100 often is rather small, leak tests on electrical bushings have proven difficult to perform. Moreover, modern medical devices require a plurality of electrical bushings 100. Accordingly, the bushing support 900 serves as a foundation for at least one electrical bushing 100 and a channel element 910 that serves for testing the hermetical sealing of both the electrical bushing 100 and of the firmly bonded connections between the bushing supports 900 and the electrical bushings 100. The channel element 910 can be used, for example, for testing for hermetical sealing and is designed such that it establishes a gas-permeable connection between an upper region 901 and a lower region 902 of the bushing support 900. Accordingly, helium, for example, can be guided through the channel element 910 into the lower region 902. A leak test device is then used to test whether or not the helium penetrates through connection sites between the bushing support and the electrical bushing and/or the individual components of the electrical bushing 100. If this is not the case, the hermetical sealing of both the bushing support 900 and of the electrical bushings 100 integrated therein is proven. Subsequently, the bushing support 900 can be welded to the housing part 26 in a firmly bonded manner. A closure means 930 closing the feedthrough channel 920 is used to close the channel element 910. This is effected in the scope of welding in a firmly bonded manner.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. An electrical bushing for use in a housing of an active implantable medical device;
whereby the electrical bushing comprises at least one electrically insulating base body and at least one electrical conducting element;
whereby the conducting element establishes, through the base body, at least one electrically conductive connection between an internal space of the housing and an external space;
whereby the conducting element is hermetically sealed with respect to the base body;
whereby the at least one conducting element comprises at least one cermet;
characterized in that the base body comprises a contact region, whereby the base body is coupled to the housing by means of the contact region.

2. The electrical bushing according to claim 1, characterized in that the base body is coupled to the titanium-comprising housing in a firmly bonded manner by means of the contact region.

3. The electrical bushing according to claim 1, characterized in that the contact region is coupled to the housing in a firmly bonded manner by means of a soldered connection or a sintered connection.

4. The electrical bushing according to claim 1, characterized in that the contact region is and/or contains a metallic coating on the base body.

5. The electrical bushing according to claim 1, characterized in that the base body is provided as a flat ceramic disc.

6. The electrical bushing according to claim 1, characterized in that the base body comprises at least one centering element, whereby the at least one centering element has a shape that is complementary, at least in part, to the shape of an opening in the housing in order to enable positioning of the electrical bushing in the housing.

7. The electrical bushing according to claim 6, characterized in that the centering element is arranged on an underside of the base body that faces towards the housing.

8. A bushing support for use in a housing of an active implantable medical device,
whereby the implantable medical device comprises an electrical bushing comprising at least one electrically insulating base body and at least one electrical conducting element;
whereby the conducting element establishes, through the base body, at least one electrically conductive connection between an internal space of the housing and an external space;
whereby the conducting element is hermetically sealed with respect to the base body;
whereby the at least one conducting element comprises at least one cermet;
characterized in that the base body comprises a contact region, whereby the base body is coupled to the housing by means of the contact region.

9. The bushing support according to claim 8, characterized in that the bushing support comprises at least one channel element, whereby the channel element establishes, through the bushing support, at least one a gas-permeable connection between an upper region of the bushing support and a lower region.

10. A housing for an active implantable medical device,
whereby the housing comprises at least one electrical bushing;
whereby the electrical bushing comprises at least one electrically insulating base body and at least one electrical conducting element;
whereby the conducting element is configured to establish, through the base body, at least one electrically conductive connection between an internal space of the housing and an external space;
whereby the conducting element is hermetically sealed with respect to the base body;
whereby the at least one conducting element comprises at least one cermet;
characterized in that the base body comprises a contact region,
whereby the base body is coupled to the housing in a firmly bonded manner by means of the contact region.

11. The housing according to claim 10, characterized in that the housing comprises a bushing support, whereby the contact region of the base body of the electrical bushing is connected to the bushing support of the housing in a firmly bonded manner.

12. An active implantable medical device having a housing,
whereby the housing comprises at least one electrical bushing;
whereby the electrical bushing comprises at least one electrically insulating base body and at least one electrical conducting element;
whereby the conducting element establishes, through the base body, at least one electrically conductive connection between an internal space of the housing and an external space;
whereby the conducting element is hermetically sealed with respect to the base body;
whereby the at least one conducting element comprises at least one cermet;
characterized in that the base body comprises a contact region,
whereby the base body is coupled to the housing in a firmly bonded manner by means of the contact region.
